(19) United States
(12) Patent Application Publication
(10) Pub. No.: US 2026/0313998 A1
(43) Pub. Date: Oct. 8, 2026

(54) SILICON CARBIDE SUBSTRATE, SILICON CARBIDE EPITAXIAL SUBSTRATE, AND METHOD OF MANUFACTURING SILICON CARBIDE SEMICONDUCTOR DEVICE

(71) Applicant: Sumitomo Electric Industries, Ltd., Osaka (JP)

(72) Inventors: Takahiro SHIIHARA, Osaka (JP); Kyoko OKITA, Osaka (JP)

(73) Assignee: Sumitomo Electric Industries, Ltd., Osaka (JP)

(21) Appl. No.: 19/484,388

(22) PCT Filed: May 10, 2024
(86) PCT No.: PCT/JP2024/017407

§ 371 Date: Nov. 14, 2025

(30) Foreign Application Priority Data
May 19, 2023 (JP) 2023-083127

(51) Int. Cl. H10D 62/832; C30B 23/02; C30B 29/36; H10D 30/01; H10D 30/66; H10P 14/20; H10P 14/24

(52) U.S. Cl. CPC H10D 62/8325; C30B 23/025; C30B 29/36; H10D 30/0297; H10D 30/668; H10P 14/24; H10P 14/2904; H10P 14/3408

(57) ABSTRACT

When a first intensity is defined as an intensity of a Raman spectrum at a Raman shift of 1300 cm⁻¹, and a second intensity is defined as an intensity of a maximum peak of the Raman spectrum in a Raman shift range of 1300 cm⁻¹ or more and 1800 cm⁻¹ or less, a ratio of the second intensity to the first intensity is equal to or greater than 1.03 and equal to or less than 1.12.

### TECHNICAL FIELD

The present disclosure relates to a silicon carbide substrate, a silicon carbide epitaxial substrate, and a method of manufacturing a silicon carbide semiconductor device. The present application claims priority based on Japanese Patent Application No. 2023-083127 filed on May 19, 2023. The entire contents of this Japanese patent application are incorporated herein by reference.

### BACKGROUND ART

Japanese Patent Laying-Open No. 2011-178622 (PTL 1) describes an apparatus of manufacturing a silicon carbide crystal, including a crucible and a heat insulating material.

### CITATION LIST

### Patent Literature

PTL 1: Japanese Patent Laying-Open No. 2011-178622

### SUMMARY OF INVENTION

In a silicon carbide substrate according to the present disclosure, when a first intensity is defined as an intensity of a Raman spectrum at a Raman shift of 1300 cm⁻¹, and a second intensity is defined as an intensity of a maximum peak of the Raman spectrum in a Raman shift range of 1300 cm⁻¹ or more and 1800 cm⁻¹ or less, a ratio of the second intensity to the first intensity is equal to or greater than 1.03 and equal to or less than 1.12.

### BRIEF DESCRIPTION OF DRAWINGS

FIG. 1 is a schematic plan view showing a configuration of a silicon carbide substrate according to the present embodiment.

FIG. 2 is a schematic cross-sectional view taken along line 11-11 of FIG. 1.

FIG. 3 is a schematic diagram showing a configuration of a Raman spectrometer.

FIG. 4 is a schematic diagram showing an example Raman spectrum of the silicon carbide substrate.

FIG. 5 is a schematic diagram showing a shape around a first peak of the Raman spectrum of the silicon carbide substrate according to the present embodiment.

FIG. 6 is a schematic diagram showing shapes around a second peak and a third peak of the Raman spectrum of the silicon carbide substrate according to the present embodiment.

FIG. 7A is a schematic diagram showing a shape of a Raman spectrum of a silicon carbide substrate according to a first modification of the present embodiment.

FIG. 7B is a schematic diagram showing a shape of a Raman spectrum of a silicon carbide substrate according to a second modification of the present embodiment.

FIG. 8 is a schematic partial cross-sectional view showing a configuration of a first example of an apparatus of manufacturing a silicon carbide ingot.

FIG. 9 is a schematic partial cross-sectional view showing a configuration of a second example of the apparatus of manufacturing a silicon carbide ingot.

FIG. 10 is a schematic diagram showing a step of performing chemical mechanical polishing on the silicon carbide substrate.

FIG. 11 is a flow diagram schematically showing a method of manufacturing a silicon carbide semiconductor device according to the present embodiment.

FIG. 12 is a schematic cross-sectional view showing a configuration of a silicon carbide epitaxial substrate according to the present embodiment.

FIG. 13 is a schematic cross-sectional view showing a step of forming a body region.

FIG. 14 is a schematic cross-sectional view showing a step of forming a source region.

FIG. 15 is a schematic cross-sectional view showing a step of forming a trench in a third main surface of a silicon carbide epitaxial layer.

FIG. 16 is a schematic cross-sectional view showing a step of forming a gate insulating film.

FIG. 17 is a schematic cross-sectional view showing a step of forming a gate electrode and an interlayer insulating film.

FIG. 18 is a schematic cross-sectional view showing a configuration of the silicon carbide semiconductor device according to the present embodiment.

### DETAILED DESCRIPTION

### Problem to be Solved by the Present Disclosure

An object of the present disclosure is to provide a silicon carbide substrate, a silicon carbide epitaxial substrate, and a method of manufacturing a silicon carbide semiconductor device that can suppress incorporation of carbon-based impurities.

### Advantageous Effect of the Present Disclosure

According to an aspect of the present disclosure, there can be provided a silicon carbide substrate, a silicon carbide epitaxial substrate, and a method of manufacturing a silicon carbide semiconductor device that can suppress incorporation of carbon-based impurities

### DESCRIPTION OF EMBODIMENTS

(1) In a silicon carbide substrate 100 according to the present disclosure, when a first intensity is defined as an intensity of a Raman spectrum at a Raman shift of 1300 cm⁻¹, and a second intensity is defined as an intensity of a maximum peak of the Raman spectrum in a Raman shift range of 1300 cm⁻¹ or more and 1800 cm⁻¹ or less, a ratio of the second intensity to the first intensity is equal to or greater than 1.03 and equal to or less than 1.12.
(2) In a silicon carbide substrate 100 according to the present disclosure, when a first wavenumber is defined as a Raman shift at which an intensity of a Raman spectrum is maximum in a Raman shift range of 1300 cm⁻¹ or more and 1800 cm⁻¹ or less, a second wavenumber is defined as a Raman shift apart from the first wavenumber by 30 cm⁻¹ to a lower wavenumber side, a first intensity ratio is defined as an intensity ratio of the Raman spectrum at the first wavenumber, a second intensity ratio is defined as an intensity ratio of the Raman spectrum at the second wavenumber, a first intensity ratio difference is defined as a value obtained by subtracting the second intensity ratio from the first intensity ratio, and a second intensity ratio difference is defined as a value obtained by subtracting 1 from the first intensity ratio, the first intensity ratio is less than 1.03, or the first intensity ratio difference is less than 50% of the second intensity ratio difference.
(3) In silicon carbide substrate 100 according to (1) or (2), a half width of a peak of the Raman spectrum in a Raman shift range of 964 cm⁻¹±50 cm⁻¹ may be equal to or less than 50 cm⁻¹.
(4) In silicon carbide substrate 100 according to any one of (1) to (3), when a first peak is defined as a peak of the Raman spectrum in a Raman shift range of 964 cm⁻¹±50 cm⁻¹, a third wavenumber is defined as a Raman shift of the first peak, and a fourth wavenumber is defined as a Raman shift of the Raman spectrum having an intensity equal to one-half of an intensity of the first peak and located on a higher wavenumber side relative to the third wavenumber, a value obtained by subtracting the third wavenumber from the fourth wavenumber may be equal to or less than 20 cm⁻¹.
(5) In silicon carbide substrate 100 according to any one of (1) to (4), silicon carbide substrate 100 may have a maximum diameter equal to or greater than 150 mm.
(6) A silicon carbide epitaxial substrate 200 according to the present disclosure includes: silicon carbide substrate 100 according to any one of (1) to (5); and a silicon carbide epitaxial layer 20 provided on silicon carbide substrate 100.
(7) A method of manufacturing a silicon carbide semiconductor device 400 according to the present disclosure includes: preparing silicon carbide epitaxial substrate 200 according to claim (6); and forming an electrode on silicon carbide epitaxial layer 20

### DETAILS OF EMBODIMENTS OF THE PRESENT DISCLOSURE

Hereinafter, embodiments of the present disclosure will be described based on the drawings. It should be noted that the same or corresponding parts in the drawings below are denoted by the same reference numbers and description thereof will not be repeated. Regarding crystallographic indications in the present specification, an individual orientation is represented by [ ], a group orientation is represented by < >, an individual plane is represented by ( ), and a group plane is represented by { }. In addition, a negative index is supposed to be crystallographically indicated by putting “-” (bar) above a numeral, but is indicated by putting the negative sign before the numeral in the present specification.

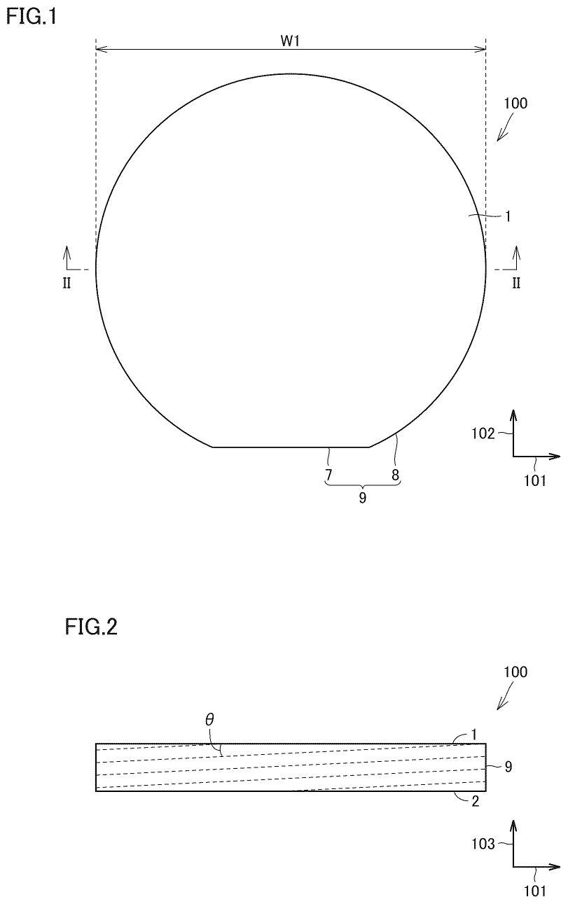

First, a configuration of a silicon carbide substrate 100 according to the present embodiment is described. FIG. 1 is a schematic plan view showing the configuration of silicon carbide substrate 100 according to the present embodiment. FIG. 2 is a schematic cross-sectional view taken along line 11-11 of FIG. 1.

As shown in FIGS. 1 and 2, silicon carbide substrate 100 according to the present embodiment mainly has a first main surface 1, a second main surface 2, and an outer circumferential surface 9. As shown in FIG. 2, second main surface 2 is opposite to first main surface 1. Outer circumferential surface 9 is contiguous to each of the first main surface and the second main surface.

The polytype of silicon carbide that forms silicon carbide substrate 100 is 4H, for example. The polytype of silicon carbide that forms silicon carbide substrate 100 may be 6H, for example. Silicon carbide substrate 100 contains an n type impurity such as nitrogen (N). Silicon carbide substrate 100 has n type conductivity, for example. A concentration of the n type impurity in silicon carbide substrate 100 is equal to or greater than 1×10¹⁷ cm⁻³ and equal to or less than 1×10²⁰ cm⁻³, for example.

A maximum diameter W1 of silicon carbide substrate 100 is equal to or greater than 150 mm, for example. Maximum diameter W1 of silicon carbide substrate 100 may be equal to or greater than 200 mm, or equal to or greater than 250 mm, for example. Maximum diameter W1 of silicon carbide substrate 100 may be equal to or less than 300 mm, for example. Maximum diameter W1 of silicon carbide substrate 100 is the longest linear distance between two different points on outer circumferential surface 9 when viewed along a line perpendicular to first main surface 1.

First main surface 1 is a {0001} plane or a plane inclined at an off angle greater than 0° and equal to or less than 8° relative to the {0001} plane, for example. The off angle may be equal to or greater than 10, or equal to greater than 2°, for example. The off angle may be equal to or less than 7°, or equal to or less than 6°. Specifically, first main surface 1 may be a {0001} plane or a plane inclined at an off angle greater than 0° and equal to or less than 8° relative to the {0001} plane. First main surface 1 may be a (000-1) plane or a plane inclined at an off angle greater than 0° and equal to or less than 8° relative to the (000-1) plane. A direction of inclination of first main surface 1 is a <11-20> direction, for example.

As shown in FIG. 1, outer circumferential surface 9 may have an orientation flat 7 and an arc-shaped portion 8, for example. Orientation flat 7 extends along a first direction 101, for example. Arc-shaped portion 8 is contiguous to orientation flat 7.

First direction 101 is parallel to first main surface 1. First direction 101 is the <11-20> direction, for example. First direction 101 may be a direction including a <11-20> direction component. A second direction 102 is a direction perpendicular to first direction 101. Second direction 102 is parallel to first main surface 1. Second direction 102 is a <1-100> direction, for example. Second direction 102 may be a direction including a <1-100> direction component, for example. A third direction 103 is a direction perpendicular to each of first direction 101 and second direction 102.

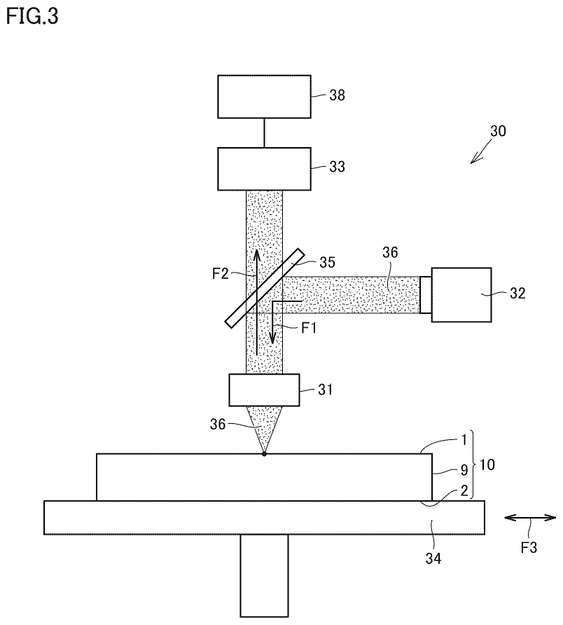

Next, a configuration of a Raman spectrometer for measuring a Raman spectrum is described. FIG. 3 is a schematic diagram showing the configuration of the Raman spectrometer.

As shown in FIG. 3, a Raman spectrometer 30 mainly has a light source 32, an objective lens 31, a spectroscope 33, a stage 34, a beam splitter 35, and a detector 38, for example. As Raman spectrometer 30, LabRAM HR-800 manufactured by HORIBA JOBIN YVON can be used. Light source 32 is a YAG (Yttrium Aluminum Garnet) laser. Light source 32 has an excitation wavelength of 532 nm. Intensity of laser irradiation is 0.5 mW. Backscattering measurement is used as a measurement method. Objective lens 31 has a magnification of 100×. A measurement area has a diameter of 1 μm. A time of laser irradiation is from 20 seconds to 180 seconds. The number of times of integration is two. A filter is D1. A grating is 300 gr/mm. A hole is 100.

Next, a method of measuring a Raman spectrum is described.

First, incident light 36 is emitted from the YAG laser of light source 32. As indicated by a first arrow F1 in FIG. 3, incident light 36 is reflected by beam splitter 35 and is emitted toward first main surface 1 of silicon carbide substrate 100. Raman spectrometer 30 employs a confocal optical system, for example. In the confocal optical system, a confocal aperture (not shown) with a circular opening is disposed at a position conjugate to a focal point of objective lens 31. This allows for detection of light only at a focused position

As indicated by a second arrow F2 in FIG. 3, Raman scattered light scattered by silicon carbide substrate 100 passes through beam splitter 35 and is introduced into spectroscope 33. In spectroscope 33, the Raman scattered light is resolved for each wavenumber. The Raman scattered light resolved for each wavenumber is detected by detector 38. Thus, a Raman spectrum with a Raman shift (wavenumber) on the horizontal axis and an intensity of the Raman scattered light on the vertical axis is obtained. Stage 34 is movable in a direction parallel to first main surface 1 of silicon carbide substrate 100 (a direction of a third arrow F3). As shown in FIG. 3, the Raman spectrum is measured at the center of first main surface 1.

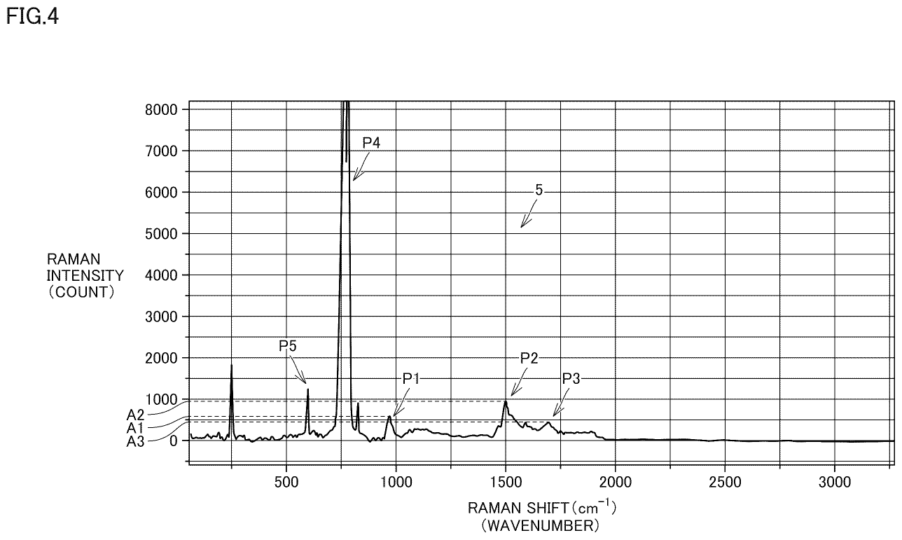

FIG. 4 is a schematic diagram showing an example Raman spectrum of silicon carbide substrate 100. The horizontal axis in FIG. 4 is a Raman shift (wavenumber). The vertical axis in FIG. 4 is an intensity of Raman scattered light (Raman intensity). The Raman shift is the difference between a wavenumber of excitation light and a wavenumber of Raman scattered light from an object to be measured. As shown in FIG. 4, a plurality of peaks are observed in a Raman spectrum 5

A first peak P1 is Raman scattered light resulting from a folded mode of a longitudinal optical (LO) branch. First peak P1 appears around a Raman shift of 964 cm⁻¹, for example. Specifically, first peak P1 appears in a Raman shift range of 964 cm⁻¹±50 cm⁻¹. First peak P1 may appear in a Raman shift range of 964 cm⁻¹±40 cm⁻¹, in a Raman shift range of 964 cm⁻¹±30 cm⁻¹, or in a Raman shift range of 964 cm⁻¹±20 cm⁻¹.

A fourth peak P4 is Raman scattered light resulting from a folded mode of a transverse optical (TO) branch. Fourth peak P4 appears around 776 cm⁻¹, for example. A fifth peak P5 is Raman scattered light resulting from a folded mode of a longitudinal acoustic (LA) branch. Fifth peak P5 appears around 610 cm⁻¹, for example.

When silicon carbide substrate 100 contains carbon-based impurities such as graphite, peaks of the Raman spectrum resulting from the carbon-based impurities are observed. Specifically, the Raman spectrum of silicon carbide substrate 100 may have a second peak P2 and a third peak P3. As the amount of graphite incorporated into silicon carbide substrate 100 increases, an intensity of each of second peak P2 and third peak P3 becomes higher.

Second peak P2 is Raman scattered light resulting from graphite. Second peak P2 appears around a Raman shift of 1500 cm⁻¹, for example. Specifically, second peak P2 appears in a Raman shift range of 1500 cm⁻¹±30 cm⁻¹. Second peak P2 may appear in a Raman shift range of 1500 cm⁻¹±20 cm⁻¹, or in a Raman shift range of 1500 cm⁻¹±10 cm⁻¹.

Third peak P3 is Raman scattered light resulting from graphite. Third peak P3 appears around 1700 cm⁻¹, for example. Specifically, third peak P3 appears in a Raman shift range of 1700 cm⁻¹±30 cm⁻¹. Third peak P3 may appear in a Raman shift range of 1700 cm⁻¹±20 cm⁻¹, or in a Raman shift range of 1700 cm⁻¹±10 cm⁻¹.

An intensity of first peak P1 is a first peak intensity A1. An intensity of second peak P2 is a second peak intensity A2. An intensity of third peak P3 is a third peak intensity A3. As shown in FIG. 4, second peak intensity A2 may be higher than third peak intensity A3. First peak intensity A1 may be lower than second peak intensity A2 and higher than third peak intensity A3. An intensity of the fifth peak may be higher than the intensity of first peak P1. An intensity of the fourth peak may be higher than the intensity of the fifth peak.

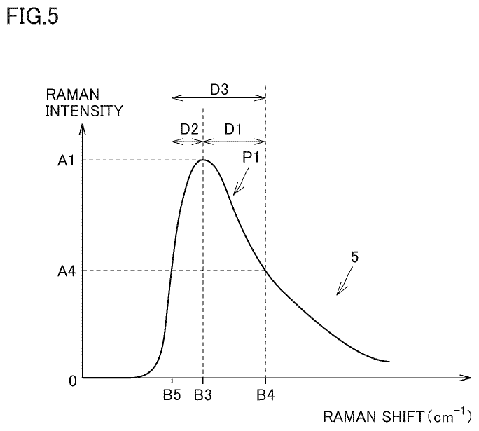

FIG. 5 is a schematic diagram showing a shape around first peak P1 of the Raman spectrum of silicon carbide substrate 100 according to the present embodiment. The horizontal axis in FIG. 5 is the Raman shift. The vertical axis in FIG. 5 is the Raman intensity.

As the amount of the carbon-based impurities incorporated into silicon carbide substrate 100 increases, the first peak becomes wider. In particular, the length of first peak P1 on the higher wavenumber side tends to be longer than the length of first peak P1 on the lower wavenumber side.

As shown in FIG. 5, the intensity around first peak P1 of Raman spectrum 5 may steeply increase from the lower wavenumber side to a local maximum value, and gradually decrease from the local maximum value to the higher wavenumber side.

Stated from a different perspective, the length of a tail of first peak P1 on the higher wavenumber side may be longer than the length of a tail of first peak P1 on the lower wavenumber side.

A Raman shift of first peak P1 is a third wavenumber B3. The intensity of first peak P1 is first peak intensity A1. An intensity equal to one-half of the intensity of first peak P1 is a fourth intensity A4. A Raman shift of the Raman spectrum having fourth intensity A4 and located on the higher wavenumber side relative to third wavenumber B3 is a fourth wavenumber B4. A Raman shift of the Raman spectrum having fourth intensity A4 and located on the lower wavenumber side relative to third wavenumber B3 is a fifth wavenumber B5.

A value obtained by subtracting fifth wavenumber B5 from fourth wavenumber B4 is a half width D3 of first peak P1. Half width D3 of first peak P1 is equal to or less than 50 cm⁻¹, for example. Half width D3 of first peak P1 may be equal to or less than 45 cm⁻¹, for example, and half width D3 of first peak P1 may be equal to or less than 40 cm⁻¹, equal to or less than 35 cm⁻¹, equal to or less than 30 cm⁻¹, equal to or less than 25 cm⁻¹, or equal to or less than 20 cm⁻¹, for example. Half width D3 of first peak P1 may be equal to or greater than 10 cm⁻¹, or equal to or greater than 15 cm⁻¹, for example.

A value obtained by subtracting third wavenumber B3 from fourth wavenumber B4 is the length of the tail of first peak P1 on the higher wavenumber side (a first length D1). First length D1 is equal to or less than 20 cm⁻¹, for example. First length D1 may be equal to or less than 15 cm⁻¹, or equal to or less than 10 cm⁻¹, for example. First length D1 may be equal to or greater than 2 cm⁻¹, or equal to or greater than 5 cm⁻¹, for example.

A value obtained by subtracting fifth wavenumber B5 from third wavenumber B3 is the length of the tail of first peak P1 on the lower wavenumber side (a second length D2). Second length D2 is smaller than first length D1. A value obtained by subtracting second length D2 from first length D1 may be equal to or greater than 1 cm⁻¹, or equal to or greater than 3 cm⁻¹, for example. The value obtained by subtracting second length D2 from first length D1 may be equal to or less than 15 cm⁻¹, or equal to or less than 10 cm⁻¹, for example.

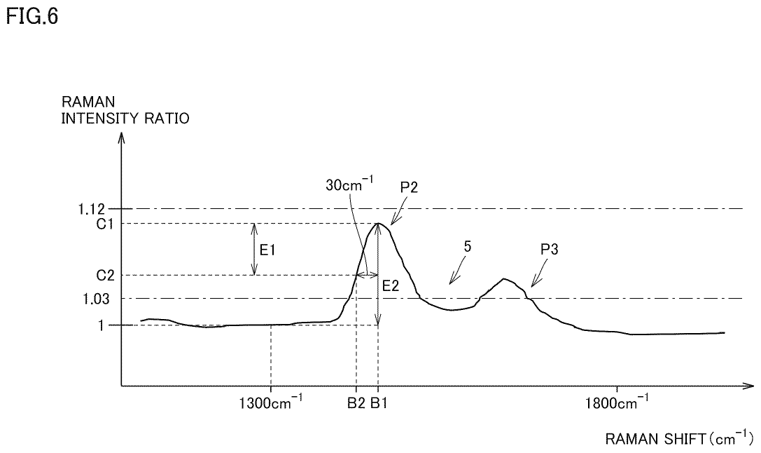

FIG. 6 is a schematic diagram showing shapes around second peak P2 and third peak P3 of the Raman spectrum of silicon carbide substrate 100 according to the present embodiment The horizontal axis in FIG. 6 is the Raman shift. The vertical axis in FIG. 6 is an intensity ratio of the Raman spectrum. Specifically, the intensity ratio of the Raman spectrum is a value obtained by dividing the intensity of the Raman spectrum by the intensity of the Raman spectrum at a Raman shift of 1300 cm⁻¹. Stated differently, the intensity of the Raman spectrum is normalized such that the intensity of the Raman spectrum at the Raman shift of 1300 cm⁻¹ is 1.

As shown in FIG. 6, the intensity ratio of the Raman spectrum of second peak P2 may be larger than the intensity ratio of the Raman spectrum of third peak P3. The intensity ratio of the Raman spectrum of second peak P2 is greater than 1 and equal to or less than 1.12, for example. The intensity ratio of the Raman spectrum of second peak P2 may be equal to or less than 1.10, equal to or less than 1.08, or equal to or less than 1.06. The intensity ratio of the Raman spectrum of second peak P2 may be equal to or greater than 1.04, or equal to or greater than 1.05.

In silicon carbide substrate 100 according to the present embodiment, when a first intensity is defined as an intensity of a Raman spectrum at a Raman shift of 1300 cm⁻¹, and a second intensity is defined as an intensity of a maximum peak of the Raman spectrum in a Raman shift range of 1300 cm⁻¹ or more and 1800 cm⁻¹ or less, a ratio of the second intensity to the first intensity is greater than 1 and equal to or less than 1.12. The maximum peak of the Raman spectrum in the Raman shift range of 1300 cm⁻¹ or more and 1800 cm⁻¹ or less corresponds to second peak P2. When the intensity of third peak P3 is higher than the intensity of second peak P2, the maximum peak of the Raman spectrum in the Raman shift range of 1300 cm⁻¹ or more and 1800 cm⁻¹ or less corresponds to third peak P3.

As shown in FIG. 6, a Raman shift at which the intensity of the Raman spectrum is maximum in the Raman shift range of 1300 cm⁻¹ or more and 1800 cm⁻¹ or less is a first wavenumber B1. A Raman shift apart from first wavenumber B1 by 30 cm⁻¹ to the lower wavenumber side is a second wavenumber B2. An intensity ratio of the Raman spectrum at first wavenumber B1 is a first intensity ratio C1. An intensity ratio of the Raman spectrum at second wavenumber B2 is a second intensity ratio C2. A value obtained by subtracting second intensity ratio C2 from first intensity ratio C1 is a first intensity ratio difference E1. A value obtained by subtracting 1 from first intensity ratio C1 is a second intensity ratio difference E2.

When first intensity ratio C1 is equal to or greater than 1.03 and first intensity ratio difference E1 is equal to or greater than 50% of second intensity ratio difference E2 in the Raman shift range of 1300 cm⁻¹ or more and 1800 cm⁻¹ or less, it is determined that the Raman spectrum has a peak. Stated differently, when first intensity ratio C1 is less than 1.03, it is determined that the Raman spectrum does not have a peak. Even if first intensity ratio C1 is equal to or greater than 1.03, when first intensity ratio difference E1 is less than 50% of second intensity ratio difference E2, it is determined that the Raman spectrum does not have a peak in the Raman shift range of 1300 cm⁻¹ or more and 1800 cm⁻¹ or less.

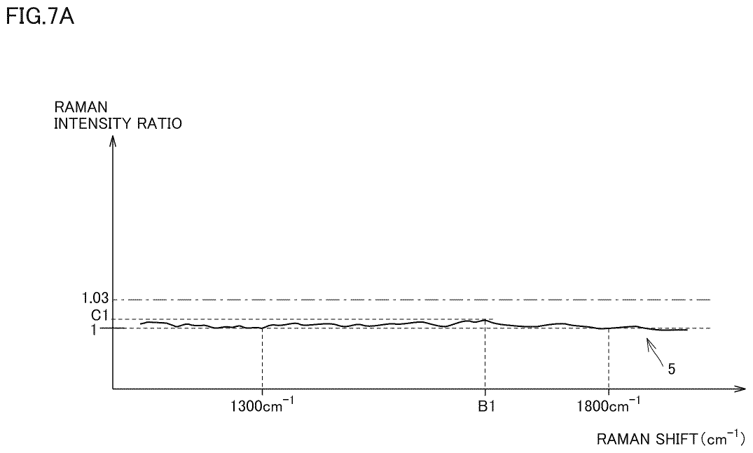

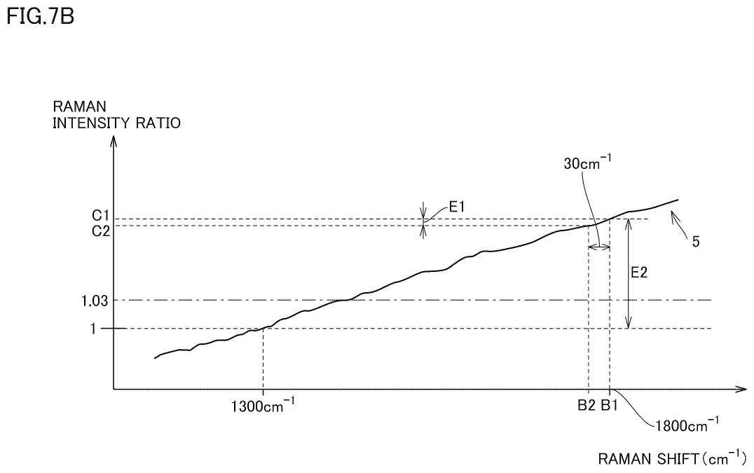

FIG. 7A is a schematic diagram showing a shape of a Raman spectrum of silicon carbide substrate 100 according to a first modification of the present embodiment. The horizontal axis in FIG. 7A is the Raman shift. The vertical axis in FIG. 7A is the intensity ratio of the Raman spectrum.

As shown in FIG. 7A, in the Raman shift range of 1300 cm⁻¹ or more and 1800 cm⁻¹ or less, the intensity ratio of the Raman spectrum to the intensity of the Raman spectrum at the Raman shift of 1300 cm⁻¹ may be less than 1.03. In other words, in the Raman shift range of 1300 cm⁻¹ or more and 1800 cm⁻¹ or less, first intensity ratio C1 is less than 1.03. In this case, it is determined that the Raman spectrum does not have a peak in the Raman shift range of 1300 cm⁻¹ or more and 1800 cm⁻¹ or less.

FIG. 7B is a schematic diagram showing a shape of a Raman spectrum of silicon carbide substrate 100 according to a second modification of the present embodiment. The horizontal axis in FIG. 7B is the Raman shift. The vertical axis in FIG. 7B is the intensity ratio of the Raman spectrum.

As shown in FIG. 7B, the intensity ratio of the Raman spectrum to the intensity of the Raman spectrum at the Raman shift of 1300 cm⁻¹ may increase while oscillating to the higher wavenumber side. In this case, first wavenumber B1, i.e., the Raman shift at which the intensity of the Raman spectrum is maximum in the Raman shift range of 1300 cm⁻¹ or more and 1800 cm⁻¹ or less, is around 1800 cm⁻¹. As shown in FIG. 7B, first intensity ratio C1, i.e., the intensity ratio of the Raman spectrum at first wavenumber B1, may be equal to or greater than 1.03.

A Raman shift apart from first wavenumber B1 by 30 cm⁻¹ to the lower wavenumber side is a second wavenumber B2. An intensity ratio of the Raman spectrum at first wavenumber B1 is a first intensity ratio C1. An intensity ratio of the Raman spectrum at second wavenumber B2 is a second intensity ratio C2. A value obtained by subtracting second intensity ratio C2 from first intensity ratio C1 is a first intensity ratio difference E1. A value obtained by subtracting 1 from first intensity ratio C1 is a second intensity ratio difference E2.

In Raman spectrum 5 shown in FIG. 7B, first intensity ratio difference E1 is less than 50% of second intensity ratio difference E2. Even if first intensity ratio C1 is equal to or greater than 1.03, when first intensity ratio difference E1 is less than 50% of second intensity ratio difference E2 in this manner, it is determined that the Raman spectrum does not have a peak in the Raman shift range of 1300 cm⁻¹ or more and 1800 cm⁻¹ or less.

Next, an apparatus of manufacturing a silicon carbide ingot 110 according to the present embodiment is described. FIG. 8 is a schematic partial cross-sectional view showing a configuration of a first example of the apparatus of manufacturing silicon carbide ingot 110. As shown in FIG. 8, an apparatus 500 of manufacturing silicon carbide ingot 110 mainly has a crucible 90, a first resistive heater 61, a second resistive heater 62, a third resistive heater 63, a molded heat insulating material 80, and a flexible heat insulating material 70.

Crucible 90 includes a source material housing portion 92 and a lid portion 91. Lid portion 91 is disposed on source material housing portion 92. First resistive heater 61 is disposed above lid portion 91. Second resistive heater 62 is disposed to surround the outer circumference of source material housing portion 92. Third resistive heater 63 is disposed below a bottom surface of source material housing portion 92.

Molded heat insulating material 80 has a first molded heat insulating material portion 81, a second molded heat insulating material portion 82, and a third molded heat insulating material portion 83. First molded heat insulating material portion 81 is disposed above first resistive heater 61. A through hole is provided at the center of first molded heat insulating material portion 81. Second molded heat insulating material portion 82 is disposed to surround each of first resistive heater 61, second resistive heater 62 and third resistive heater 63. Third molded heat insulating material portion 83 is disposed below third resistive heater 63. A through hole is provided at the center of third molded heat insulating material portion 83.

Flexible heat insulating material 70 has a first flexible heat insulating material portion 71, a second flexible heat insulating material portion 72, and a third flexible heat insulating material portion 73. First flexible heat insulating material portion 71 is disposed on a bottom surface of first molded heat insulating material portion 81. In a growth direction of silicon carbide ingot 110, first flexible heat insulating material portion 71 is located between first resistive heater 61 and first molded heat insulating material portion 81.

Second flexible heat insulating material portion 72 is disposed on an inner circumferential surface of second molded heat insulating material portion 82. In a radial direction of silicon carbide ingot 110, second flexible heat insulating material portion 72 is located between second resistive heater 62 and second molded heat insulating material portion 82. Third flexible heat insulating material portion 73 is disposed on an upper surface of third molded heat insulating material portion 83. In the growth direction of silicon carbide ingot 110, third flexible heat insulating material portion 73 is located between third resistive heater 63 and third molded heat insulating material portion 83.

As molded heat insulating material 80, for example, a product manufactured by Osaka Gas Chemicals Co., Ltd. (DON-2011) or manufactured by Nippon Carbon Co., Ltd. (FGL-203GH) is used. As flexible heat insulating material 70, for example, a product manufactured by Osaka Gas Chemicals Co., Ltd. (LFP-105) or manufactured by Nippon Techno-Carbon Co., Ltd. (GF-20-5FH) is used.

Flexible heat insulating material 70 has higher flexibility than molded heat insulating material 80. Specifically, a value of actual density relative to packed bulk density of flexible heat insulating material 70 is smaller than a value of actual density relative to packed bulk density of molded heat insulating material 80. The actual density is a weight relative to the actual volume. The packed bulk density is a weight relative to the volume when filling is done without voids. As flexibility increases, the number of voids increases, causing the actual density to be lower in value than the packed bulk density

An amount of sagging per unit pressure of flexible heat insulating material 70 is larger than an amount of sagging per unit pressure of molded heat insulating material 80. The amount of sagging per unit pressure is an amount by which a pressing portion of a pressing machine sags when the pressing portion applies a constant pressure to press the heat insulating material. The amount of sagging per unit pressure can be measured using a digimatic indicator (ID-H0530) manufactured by Mitutoyo Corporation.

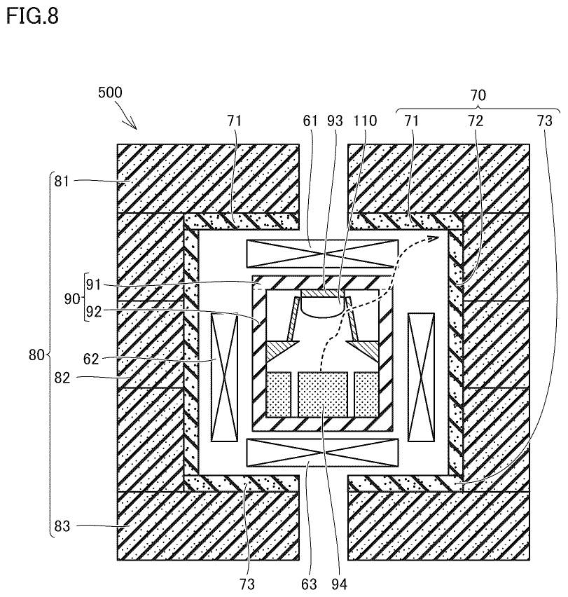

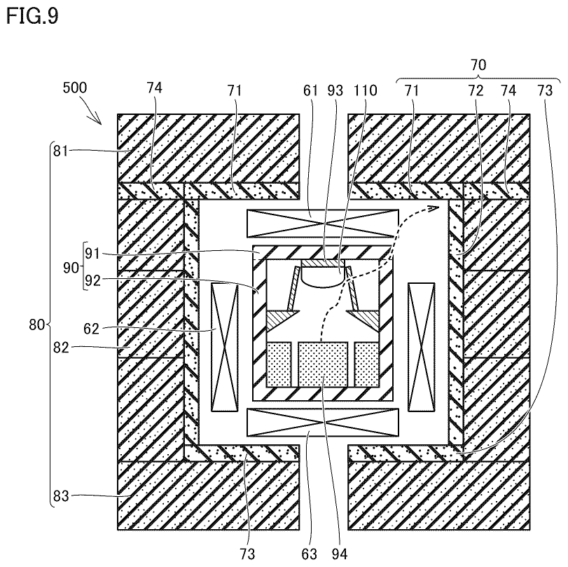

FIG. 9 is a schematic partial cross-sectional view showing a configuration of a second example of the apparatus of manufacturing silicon carbide ingot 110. The second example of the apparatus of manufacturing silicon carbide ingot 110 differs from the first example of the apparatus of manufacturing silicon carbide ingot 110 mainly in that a fourth flexible heat insulating material portion 74 is disposed between first molded heat insulating material portion 81 and second molded heat insulating material portion 82, and is otherwise substantially the same in configuration as the first example of the apparatus of manufacturing silicon carbide ingot 110. The configuration different from that of the first example of the apparatus of manufacturing silicon carbide ingot 110 is described below.

As shown in FIG. 9, apparatus 500 of manufacturing silicon carbide ingot 110 may have fourth flexible heat insulating material portion 74. Fourth flexible heat insulating material portion 74 is disposed between first molded heat insulating material portion 81 and second molded heat insulating material portion 82. Fourth flexible heat insulating material portion 74 is contiguous to first flexible heat insulating material portion 71. In the growth direction of silicon carbide ingot 110, fourth flexible heat insulating material portion 74 may have the same thickness as first flexible heat insulating material portion 71.

Next, a method of manufacturing silicon carbide substrate 100 according to the present embodiment is described.

First, a pre-sintering step is performed. Specifically, crucible 90 is heated without a silicon carbide source material 94 and a seed substrate 93 disposed therein. Specifically, crucible 90 is heated by application of power to first resistive heater 61, second resistive heater 62, and third resistive heater 63. A temperature of crucible 90 is equal to or greater than 2200° C. and equal to or less than 2400° C., for example. A pressure in crucible 90 is equal to or greater than 0.1 kPa and equal to or less than 3 kPa, for example. An atmospheric gas includes argon gas or nitrogen gas. A time of the pre-sintering step is equal to or greater than 5 hours and equal to or less than 20 hours, for example.

Next, a growth step is performed. As shown in FIGS. 8 and 9, silicon carbide source material 94 is disposed in source material housing portion 92. Seed substrate 93 is fixed to lid portion 91 with an adhesive (not shown), for example. Seed substrate 93 is disposed to face silicon carbide source material 94. Seed substrate 93 is silicon carbide substrate 100 having a 4H polytype, for example. A main surface of seed substrate 93 has a diameter of 150 mm, for example. The main surface of seed substrate 93 is a {0001} plane or a plane inclined at an off angle about equal to or less than 8° relative to the {0001} plane, for example.

Then, the pressure in crucible 90 is maintained at equal to or less than 1.0 Pa and held for about 30 minutes, without application of power to first resistive heater 61, second resistive heater 62, and third resistive heater 63. Then, crucible 90 is heated by application of power to first resistive heater 61, second resistive heater 62, and third resistive heater 63. Specifically, crucible 90 is heated under high vacuum without a flow of argon gas and nitrogen gas until the temperature of a bottom surface of crucible 90 reaches 1300° C. This removes a significant amount of impurities (for example, aluminum, titanium, iron, vanadium, boron, calcium and the like) contained in flexible heat insulating material 70. After the temperature of the bottom surface of crucible 90 reaches 1300° C., the atmospheric gas is introduced into crucible 90 to cause the pressure in crucible 90 to be equal to or greater than 0.3 kPa and equal to or less than 1.0 kPa. Then, crucible 90 is heated to a growth temperature of silicon carbide ingot 110. This initiates growth of silicon carbide ingot 110.

The pressure in crucible 90 is equal to or greater than 0.1 kPa and equal to or less than 3 kPa, for example. The temperature of crucible 90 is equal to or greater than 2200° C. and equal to or less than 2400° C., for example. Thus, silicon carbide source material 94 sublimates to produce silicon carbide gas (source gas). The silicon carbide gas recrystallizes on a surface of seed substrate 93. Thus, silicon carbide ingot 110 grows on the surface of seed substrate 93.

After the growth of silicon carbide ingot 110 is completed, the pressure in crucible 90 is adjusted to about 80 kPa. The atmospheric gas is argon gas only. With the temperature of crucible 90 being equal to or greater than 2200° C. and equal to or less than 2400° C., for example, silicon carbide ingot 110 is annealed for about 5 hours.

After the annealing is completed, silicon carbide ingot 110 is cooled to room temperature. Then, silicon carbide ingot 110 is removed from crucible 90. Then, silicon carbide ingot 110 is sliced by a wire-saw device (not shown). Thus, a plurality of silicon carbide substrates 100 are cut from silicon carbide ingot 110.

Silicon carbide substrate 100 is made of hexagonal silicon carbide having a 4H polytype, for example. Silicon carbide substrate 100 has first main surface 1 and second main surface 2 opposite to first main surface 1. First main surface 1 is a plane angled off by equal to or less than 4° in the <11-20> direction relative to the {0001} plane, for example.

Next, a step of mechanically polishing silicon carbide substrate 100 is performed. Specifically, the silicon carbide substrate is disposed such that first main surface 1 faces a surface plate (not shown). Then, slurry is introduced between first main surface 1 and the surface plate. The slurry includes diamond abrasive grains, for example. The diamond abrasive grains each have a diameter equal to or greater than 1 μm and equal to or less than 3 μm, for example. A load is applied to first main surface 1 by the surface plate. Accordingly, silicon carbide substrate 100 is mechanically polished on first main surface 1.

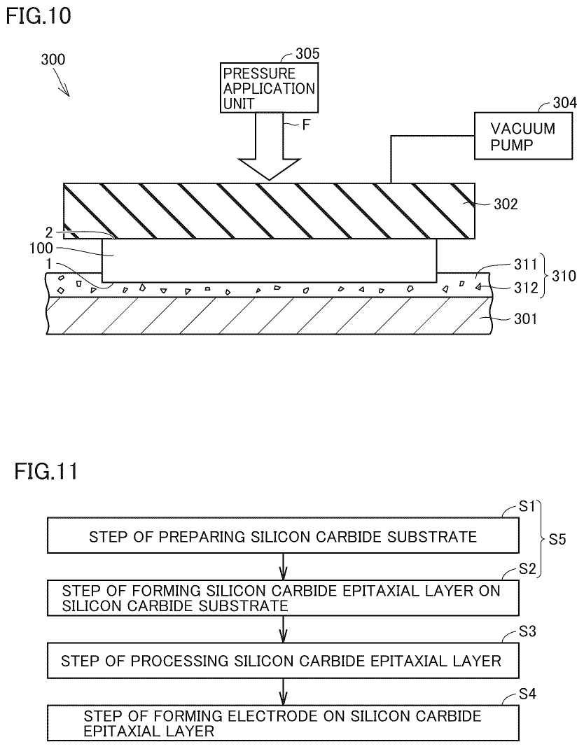

Next, a step of chemically mechanically polishing silicon carbide substrate 100 is performed FIG. 10 is a schematic diagram showing the step of performing chemical mechanical polishing on silicon carbide substrate 100. As shown in FIG. 10, a chemical mechanical polishing apparatus 300 includes a polishing cloth 301, a polishing head 302, a vacuum pump 304, and a pressure application unit 305. Polishing cloth 301 is a suede polishing cloth (SUPREME) manufactured by Nitta Haas Incorporated, for example.

As shown in FIG. 9, chemical mechanical polishing is performed on silicon carbide substrate 100 using a polishing solution 310. Polishing solution 310 includes abrasive grains 312 and an oxidizing agent 311. Abrasive grains 312 are colloidal silica, for example. The oxidizing agent is a hydrogen peroxide solution, permanganate, nitrate, hypochlorite or the like, for example. The polishing solution is DSC-0902 manufactured by Fujimi Incorporated, for example.

Silicon carbide substrate 100 is attached to polishing head 302. Silicon carbide substrate 100 is disposed to face polishing cloth 301. Polishing solution 310 is supplied between silicon carbide substrate 100 and polishing cloth 301. Polishing head 302 has a rotational speed of 60 rpm, for example. The surface plate provided with polishing cloth 301 has a rotational speed of 60 rpm, for example. An average processing surface pressure is 450 g/cm², for example. Polishing solution 310 has a flow rate of 2 liters per minute, for example. Accordingly, silicon carbide substrate 100 according to the present embodiment (FIG. 1) is obtained.

### <Method of Manufacturing Silicon Carbide Semiconductor Device>

Next, a method of manufacturing a silicon carbide semiconductor device 400 according to the present embodiment is described. FIG. 11 is a flow diagram schematically showing the method of manufacturing silicon carbide semiconductor device 400 according to the present embodiment. As shown in FIG. 11, the method of manufacturing silicon carbide semiconductor device 400 according to the present embodiment mainly includes a step of preparing a silicon carbide epitaxial substrate (S5), a step of processing a silicon carbide epitaxial layer (S3), and a step of forming an electrode on the silicon carbide epitaxial layer (S4).

First, the step of preparing a silicon carbide epitaxial substrate (S5) is performed. The step of preparing a silicon carbide epitaxial substrate (S5) includes a step of preparing a silicon carbide substrate (S1) and a step of forming a silicon carbide epitaxial layer on the silicon carbide substrate (S2). In the step of preparing a silicon carbide substrate (S1), silicon carbide substrate 100 according to the present embodiment is prepared (see FIG. 1).

Next, the step of forming a silicon carbide epitaxial layer 20 on silicon carbide substrate 100 (S2) is performed. Specifically, silicon carbide epitaxial layer 20 is formed by epitaxial growth on first main surface 1 of silicon carbide substrate 100. In the epitaxial growth, silane (SiH₄) and propane (C₃H₈) are used as a source gas, for example, and hydrogen (H₂) is used as a carrier gas. A temperature of the epitaxial growth is about equal to or greater than 1400° C. and equal to or less than 1700° C., for example. In the epitaxial growth, an n type impurity such as nitrogen is introduced into silicon carbide epitaxial layer 20. Accordingly, a silicon carbide epitaxial substrate 200 according to the present embodiment is prepared.

FIG. 12 is a schematic cross-sectional view showing a configuration of silicon carbide epitaxial substrate 200 according to the present embodiment. As shown in FIG. 12, silicon carbide epitaxial substrate 200 according to the present embodiment includes silicon carbide substrate 100 and silicon carbide epitaxial layer 20. Silicon carbide epitaxial layer 20 is provided on silicon carbide substrate 100.

Silicon carbide epitaxial layer 20 may have a buffer layer 41, a drift layer 42, and a third main surface 3. Buffer layer 41 is in contact with first main surface 1 of silicon carbide substrate 100. Drift layer 42 is provided on buffer layer 41. A concentration of nitrogen contained in drift layer 42 may be lower than a concentration of nitrogen contained in buffer layer 41. Third main surface 3 is formed by drift layer 42.

Next, the step of processing a silicon carbide epitaxial layer (S3) is performed. Specifically, silicon carbide epitaxial layer 20 is processed as described below. First, ion implantation is performed into silicon carbide epitaxial layer 20

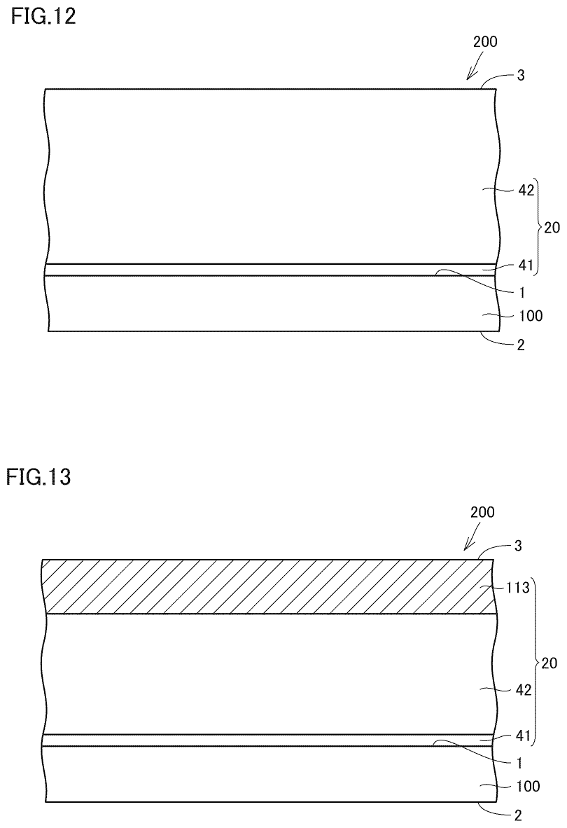

FIG. 13 is a schematic cross-sectional view showing a step of forming a body region. In the step of forming a body region, a p type impurity such as aluminum is ion-implanted into third main surface 3 of silicon carbide epitaxial layer 20. Thus, a body region 113 having p type conductivity is formed. Portions where body region 113 is not formed serve as drift layer 42 and buffer layer 41. Body region 113 has a thickness of 0.9 μm, for example. Silicon carbide epitaxial layer 20 includes buffer layer 41, drift layer 42, and body region 113.

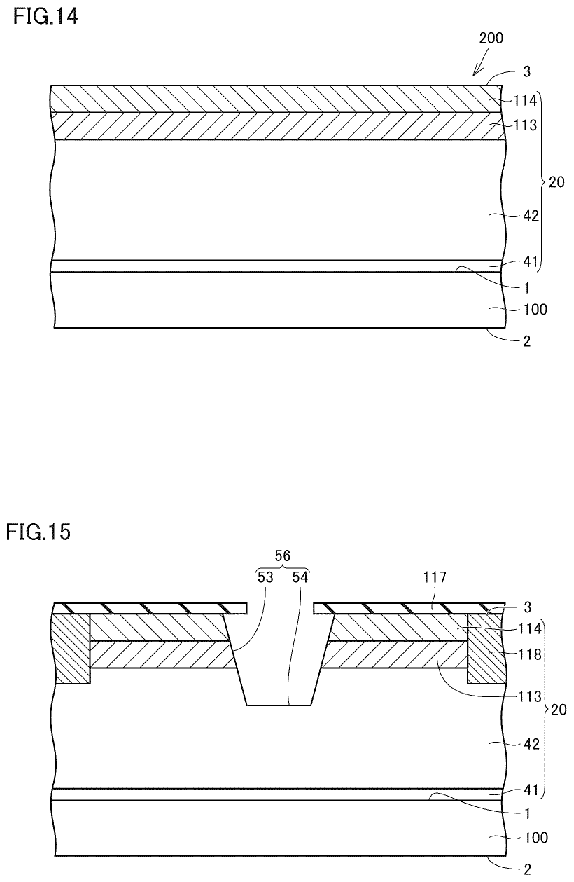

Next, a step of forming a source region is performed. FIG. 14 is a schematic cross-sectional view showing the step of forming a source region. Specifically, an n type impurity such as phosphorus is ion-implanted into body region 113. Thus, a source region 114 having n type conductivity is formed. Source region 114 has a thickness of 0.4 μm, for example. A concentration of the n type impurity contained in source region 114 is higher than a concentration of the p type impurity contained in body region 113.

Next, a p type impurity such as aluminum is ion-implanted into source region 114, to thereby form a contact region 118. Contact region 118 is formed to extend through source region 114 and body region 113 so as to be in contact with drift layer 42. A concentration of the p type impurity contained in contact region 118 is higher than the concentration of the n type impurity contained in source region 114.

Next, activation annealing is performed to activate the ion-implanted impurities. A temperature of the activation annealing is equal to or greater than 1500° C. and equal to or less than 1900° C., for example. A time of the activation annealing is about 30 minutes, for example. An atmosphere of the activation annealing is an argon atmosphere, for example.

Next, a step of forming a trench in third main surface 3 of silicon carbide epitaxial layer 20 is performed. FIG. 15 is a schematic cross-sectional view showing the step of forming a trench in third main surface 3 of silicon carbide epitaxial layer 20. A mask 117 with an opening is formed on third main surface 3 which is formed by source region 114 and contact region 118. Source region 114, body region 113, and a portion of drift layer 42 are removed by etching using mask 117. Inductively coupled plasma reactive ion etching can be used, for example, as an etching method. Specifically, inductively coupled plasma reactive ion etching using SF₆ or a mixed gas of SF₆ and O₂ as a reactive gas is used, for example. A recess is formed in third main surface 3 by the etching.

Next, thermal etching is performed in the recess. The thermal etching may be performed by heating in an atmosphere including a reactive gas having at least one type of halogen atom, for example, with mask 117 formed on third main surface 3. The at least one type of halogen atom includes at least one of a chlorine (Cl) atom and a fluorine (F) atom. The atmosphere includes Cl₂, BCl₃, SF₆ or CF₄, for example. The thermal etching is performed using a mixed gas of chlorine gas and oxygen gas as the reactive gas, for example, at a heat treatment temperature equal to or greater than 700° C. and equal to or less than 1000° C., for example. The reactive gas may include a carrier gas in addition to the above-described chlorine gas and oxygen gas. Nitrogen gas, argon gas, helium gas or the like can be used, for example, as the carrier gas.

As shown in FIG. 15, a trench 56 is formed in third main surface 3 by the thermal etching. Trench 56 is defined by a side wall surface 53 and a bottom wall surface 54. Side wall surface 53 is formed by source region 114, body region 113, and drift layer 42. Bottom wall surface 54 is formed by drift layer 42. Mask 117 is then removed from third main surface 3.

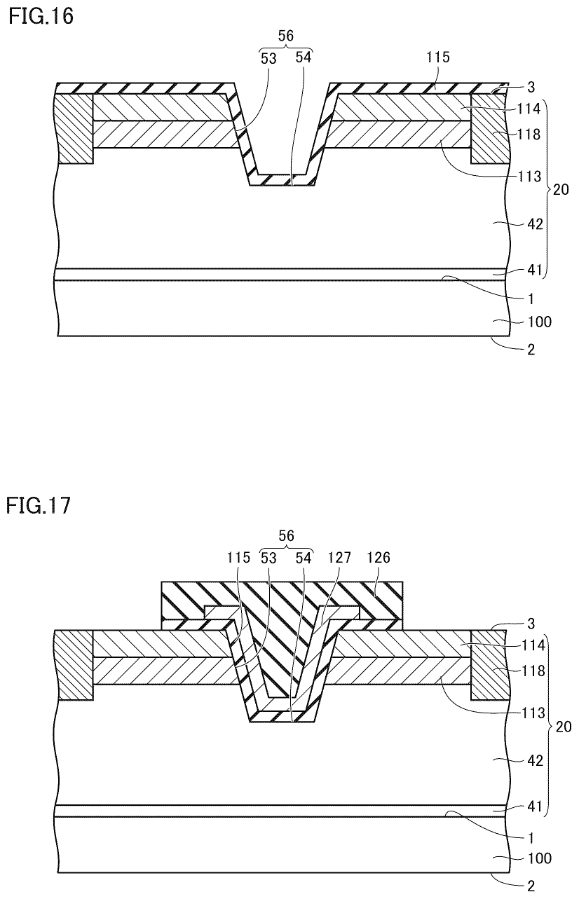

Next, a step of forming a gate insulating film is performed. FIG. 16 is a schematic cross-sectional view showing the step of forming a gate insulating film. Specifically, silicon carbide epitaxial substrate 200 provided with trench 56 in third main surface 3 is heated at a temperature equal to or greater than 1300° C. and equal to or less than 1400° C., for example, in an atmosphere including oxygen. Thus, a gate insulating film 115 is formed in contact with drift layer 42 at bottom wall surface 54, in contact with each of drift layer 42, body region 113 and source region 114 at side wall surface 53, and in contact with each of source region 114 and contact region 118 at third main surface 3.

Next, a step of forming a gate electrode is performed. FIG. 17 is a schematic cross-sectional view showing the step of forming a gate electrode and an interlayer insulating film. A gate electrode 127 is formed inside trench 56 so as to be in contact with gate insulating film 115. Gate electrode 127 is disposed inside trench 56, and is formed on gate insulating film 115 so as to face each of side wall surface 53 and bottom wall surface 54 of trench 56. Gate electrode 127 is formed by an LPCVD (Low Pressure Chemical Vapor Deposition) process, for example.

Next, an interlayer insulating film 126 is formed. Interlayer insulating film 126 is formed to cover gate electrode 127 and to be in contact with gate insulating film 115. Interlayer insulating film 126 is formed by a chemical vapor deposition process, for example. Interlayer insulating film 126 is made of a material including silicon dioxide, for example. Then, interlayer insulating film 126 and gate insulating film 115 are partially etched to form an opening above source region 114 and contact region 118. Thus, contact region 118 and source region 114 are exposed at gate insulating film 115.

Next, a step of forming a source electrode is performed. A source electrode 116 is formed in contact with each of source region 114 and contact region 118. Source electrode 116 is formed by a sputtering process, for example. Source electrode 116 is made of a material including Ti (titanium), Al (aluminum) and Si (silicon), for example.

Next, alloying annealing is performed. Specifically, source electrode 116 in contact with each of source region 114 and contact region 118 is held at a temperature equal to or greater than 900° C. and equal to or less than 1100° C., for example, for about 5 minutes. Thus, source electrode 116 is at least partially silicided. Thus, source electrode 116 in ohmic contact with source region 114 is formed. Source electrode 116 may be in ohmic contact with contact region 118.

Next, a source wire 119 is formed. Source wire 119 is electrically connected to source electrode 116. Source wire 119 is formed to cover source electrode 116 and interlayer insulating film 126

Next, a step of forming a drain electrode is performed. First, silicon carbide substrate 100 is polished on second main surface 2. Thus, silicon carbide substrate 100 has a reduced thickness. Then, a drain electrode 123 is formed. Drain electrode 123 is formed in contact with second main surface 2. Accordingly, silicon carbide semiconductor device 400 according to the present embodiment is manufactured.

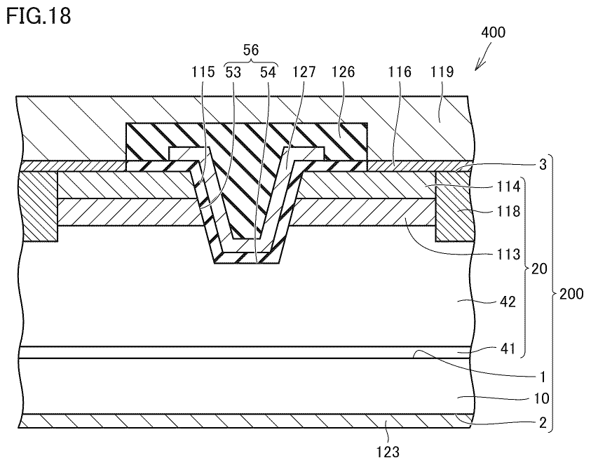

FIG. 18 is a schematic cross-sectional view showing a configuration of the silicon carbide semiconductor device according to the present embodiment. Silicon carbide semiconductor device 400 is a MOSFET (Metal Oxide Semiconductor Field Effect Transistor), for example. Silicon carbide semiconductor device 400 mainly has silicon carbide epitaxial substrate 200, gate electrode 127, gate insulating film 115, source electrode 116, drain electrode 123, source wire 119, and interlayer insulating film 126. Silicon carbide epitaxial substrate 200 has buffer layer 41, drift layer 42, body region 113, source region 114, and contact region 118. Silicon carbide semiconductor device 400 may be an IGBT (Insulated Gate Bipolar Transistor), for example.

Next, functions and effects of silicon carbide substrate 100 according to the present embodiment are described.

In manufacturing silicon carbide ingot 110, the source gas that has leaked from crucible 90 may cause degradation of molded heat insulating material 80. As molded heat insulating material 80 degrades further, gaps are formed in molded heat insulating material 80, thus creating a path through which the source gas escapes outside. In this case, the temperature of an upper portion of crucible 90 drops excessively, resulting in a large temperature difference in the vertical direction of crucible 90. Consequently, an excessive upward flow of the source gas is generated as compared to when no gaps are formed in molded heat insulating material 80.

A dashed arrow shown in each of FIGS. 8 and 9 indicates an example flow of the source gas (silicon carbide gas). The source gas tends to flow through crucible 90 toward molded heat insulating material 80 located above crucible 90.

In addition, molded heat insulating material 80 is used multiple times, causing the gaps in molded heat insulating material 80 to increase due to aging. This results in deterioration of heat insulation performance and occurrence of pressure fluctuations within crucible 90. Consequently, the temperature environment becomes less stable during crystal growth of silicon carbide ingot 110, making it difficult to achieve a desired temperature distribution within crucible 90. As a result, the crystal quality of silicon carbide ingot 110 may be affected.

In particular, the degradation of molded heat insulating material 80 located above crucible 90 increases the temperature difference in the vertical direction of crucible 90. Consequently, an excessive upward flow of the source gas is generated, and therefore, carbon-based impurities tend to be stirred up from carbon members that form crucible 90, a carbonized source material, and the like. As a result, the carbon-based impurities are incorporated into grown silicon carbide ingot 110.

As a result of intensive studies on how to suppress the generation of the excessive upward flow of the source gas, the inventors made the following findings.

First, flexible heat insulating material 70 having appropriate flexibility was disposed in the vicinity of molded heat insulating material 80. When flexible heat insulating material 70 has high flexibility, flexible heat insulating material 70 can be embedded into a joint between two molded heat insulating materials 80. It is thus possible to fill a gap between two molded heat insulating materials 80 that results from assembly variations, design errors, and the like. By sandwiching flexible heat insulating material 70 between upper and lower molded heat insulating materials 80, the gap between these two molded heat insulating materials 80 can be further filled by the weight of upper molded heat insulating material 80.

When the flexibility is excessively high, on the other hand, the source gas readily permeates through flexible heat insulating material 70. Consequently, it is not possible to sufficiently suppress the degradation of molded heat insulating material 80. The degree of flexibility of molded heat insulating material 80 is evaluated based on the ratio of actual density to packed bulk density and on the amount of sagging per unit pressure.

According to the present disclosure, by disposing flexible heat insulating material 70 having appropriate flexibility in the vicinity of molded heat insulating material 80, it is possible to suppress the formation of the path in molded heat insulating material 80 through which the source gas escapes outside. As a result, it is possible to suppress the generation of the excessive upward flow of the source gas. Therefore, silicon carbide substrate 100 that suppresses the incorporation of the carbon-based impurities can be obtained.

### EXAMPLES

### Preparation of Samples

First, silicon carbide substrates 100 according to Samples 1 to 3 were prepared. Silicon carbide substrate 100 according to Sample 1 was a comparative example. Silicon carbide substrates 100 according to Samples 2 and 3 were examples. Silicon carbide substrates 100 according to Sample 1, Sample 2 and Sample 3 were manufactured using an apparatus A, an apparatus B and an apparatus C, respectively. Apparatus B is the manufacturing apparatus shown in FIG. 8. Apparatus C is the apparatus shown in FIG. 9. Apparatus A has molded heat insulating material 80, but does not have flexible heat insulating material 70.

The property of each of molded heat insulating material 80 and flexible heat insulating material 70 is shown in Table 1. In apparatus A, the density ratio of molded heat insulating material 80 was 0.99. In apparatus B, the density ratio of molded heat insulating material 80 was 0.98. In apparatus C, the density ratio of molded heat insulating material 80 was 0.99. In Table 1, the density ratio is a ratio of actual density to packed bulk density.

TABLE 1

| Conditions | Sample No. | | Sample 1 | Sample 2 | Sample 3 |
|---|---|---|---|---|---|
| | Apparatus structure | | Apparatus A | Apparatus B | Apparatus C |
| | Density | Molded heat | 0.99 | 0.98 | 0.99 |
| | ratio | insulating material | | | |
| | | (A) | | | |
| | | Flexible heat | Not provided | 0.95 | 0.91 |
| | | insulating material | | | |
| | | (B) | | | |
| | | B/A | — | 97% | 92% |
| | Amount of | Molded heat | 0.58 | 0.53 | 0.60 |
| | sagging | insulating material | | | |
| | (mm/N) | Flexible heat | Not provided | 2.04 | 1.72 |
| | | insulating material | | | |

| | | | | |
|---|---|---|---|---|
| | Pre-sintering step | Not performed | Performed | Performed |
| Results | Intensity ratio of | 1.13 | 1.08 | 1.01 |
| | maximum peak | | | |
| | in range from 1300 cm⁻¹ to | | | |
| | 1800 cm⁻¹ | | | |
| | Half width of | 120 | 40 | 20 |
| | first peak (cm⁻¹) | | | |
| | Length of tail | 100 | 20 | 10 |
| | of first peak on | | | |
| | higher wavenumber | | | |
| | side (cm⁻¹) | | | |

Apparatus A does not have flexible heat insulating material 70. In apparatus B, the density ratio of flexible heat insulating material 70 was 0.95. In apparatus C, the density ratio of flexible heat insulating material 70 was 0.91. In apparatus B, the density ratio of flexible heat insulating material 70 to the density ratio of molded heat insulating material 80 (B/A) was 97%. In apparatus C, the density ratio of flexible heat insulating material 70 to the density ratio of molded heat insulating material 80 (B/A) was 92%.

In Table 1, the amount of sagging is an amount of sagging per unit pressure. In apparatus A, the amount of sagging of molded heat insulating material 80 was 0.58 mm/N. In apparatus B, the amount of sagging of molded heat insulating material 80 was 0.53 mm/N. In apparatus C, the amount of sagging of molded heat insulating material 80 was 0.60 mm/N. In apparatus B, the amount of sagging of flexible heat insulating material 70 was 2.04 mm/N. In apparatus C, the amount of sagging of flexible heat insulating material 70 was 1.72 mm/N.

As shown in Table 1, a pre-sintering step was not performed in apparatus A. The pre-sintering step was performed in apparatus B and apparatus C. In the pre-sintering step, a temperature of crucible 90 was 2300° C. A pressure in crucible 90 was 0.5 kPa. An atmospheric gas was a mixed gas of argon gas and nitrogen gas. A time of the pre-sintering step was 18 hours.

### (Evaluation Method)

Next, the Raman spectra of silicon carbide substrates 100 according to Sample 1, Sample 2 and Sample 3 were measured. As Raman spectrometer 30, LabRAM HR-800 manufactured by HORIBA JOBIN YVON was used. Light source 32 was a YAG laser. Light source 32 had an excitation wavelength of 532 nm. Intensity of laser irradiation was 0.5 mW. Backscattering measurement was used as a measurement method. Objective lens 31 had a magnification of 100×. A measurement area had a diameter of 1 μm. A time of laser irradiation was from 20 seconds to 180 seconds. The number of times of integration was two. A filter was D1. A grating was 300 gr/mm. A hole was 100.

### (Evaluation Results)

As the concentration of carbon-based impurities in silicon carbide substrate 100 increases, the intensity of a maximum peak of the Raman spectrum in a Raman shift range of 1300 cm⁻¹ or more and 1800 cm⁻¹ or less tends to increase. Further, half width D3 of first peak P1 increases. In particular, the length of the tail of first peak P1 on the higher wavenumber side becomes longer.

As shown in Table 1, the intensity ratios of the maximum peaks in the range from 1300 cm⁻¹ to 1800 cm⁻¹ that were measured on first main surfaces 1 of silicon carbide substrates 100 according to Samples 1 to 3 were 1.13, 1.08 and 1.01, respectively. The intensity ratio of the maximum peak in the range from 1300 cm⁻¹ to 1800 cm⁻¹ is a value obtained by dividing the intensity of the maximum peak of the Rama spectrum in the Raman shift range of 1300 cm⁻¹ or more and 1800 cm⁻¹ or less by the intensity of the Raman spectrum at a Raman shift of 1300 cm⁻¹.

Half widths D3 of first peaks P1 that were measured on first main surfaces 1 of silicon carbide substrates 100 according to Samples 1 to 3 were 120 cm⁻¹, 40 cm⁻¹ and 20 cm⁻¹, respectively. The lengths of the tails of first peaks P1 on the higher wavenumber side that were measured on first main surfaces 1 of silicon carbide substrates 100 according to Samples 1 to 3 were 100 cm⁻¹, 20 cm⁻¹ and 10 cm⁻¹, respectively.

In view of the above results, it was confirmed that silicon carbide substrate 100 according to each of Samples 2 and 3 could suppress incorporation of carbon-based impurities as compared to silicon carbide substrate 100 according to Sample 1.

It should be understood that the embodiments and examples disclosed herein are illustrative and non-restrictive in every respect. The scope of the present invention is defined by the terms of the claims, rather than the description above, and is intended to include any modifications within the meaning and scope equivalent to the terms of the claims.

### REFERENCE SIGNS LIST

1 first main surface; 2 second main surface; 3 third main surface; 5 Raman spectrum; 7 orientation flat; 8 arc-shaped portion; 9 outer circumferential surface; 20 silicon carbide epitaxial layer; 30 Raman spectrometer; 31 objective lens; 32 light source; 33 spectroscope; 34 stage; 35 beam splitter; 36 incident light; 38 detector; 41 buffer layer; 42 drift layer, 53 side wall surface; 54 bottom wall surface; 56 trench; 61 first resistive heater; 62 second resistive heater; 63 third resistive heater; 70 flexible heat insulating material; 71 first flexible heat insulating material portion; 72 second flexible heat insulating material portion; 73 third flexible heat insulating material portion; 74 fourth flexible heat insulating material portion; 80 molded heat insulating material; 81 first molded heat insulating material portion; 82 second molded heat insulating material portion; 83 third molded heat insulating material portion; 90 crucible, 91 lid portion; 92 source material housing portion; 93 seed substrate; 94 silicon carbide source material; 100 silicon carbide substrate; 101 first direction; 102 second direction; 103 third direction; 110 silicon carbide ingot; 113 body region; 114 source region; 115 gate insulating film; 116 source electrode; 117 mask; 118 contact region; 119 source wire; 123 drain electrode; 126 interlayer insulating film; 127 gate electrode; 200 silicon carbide epitaxial substrate; 300 chemical mechanical polishing apparatus; 301 polishing cloth; 302 polishing head; 304 vacuum pump; 305 pressure application unit; 310 polishing solution; 311 oxidizing agent; 312 abrasive grain; 400 silicon carbide semiconductor device; 500 manufacturing apparatus; A1 first peak intensity; A2 second peak intensity. A3 third peak intensity, A4 fourth peak intensity; B1 first wavenumber; B2 second wavenumber, B3 third wavenumber; B4 fourth wavenumber; B5 fifth wavenumber; C1 first intensity ratio; C2 second intensity ratio; D1 first length; D2 second length; D3 half width; E1 first intensity ratio difference; E2 second intensity ratio difference; F1 first arrow; F2 second arrow; F3 third arrow; P1 first peak; P2 second peak; P3 third peak; P4 fourth peak; P5 fifth peak; W1 maximum diameter.

1. A silicon carbide substrate, wherein
when a first intensity is defined as an intensity of a Raman spectrum at a Raman shift of 1300 cm⁻¹, and a second intensity is defined as an intensity of a maximum peak of the Raman spectrum in a Raman shift range of 1300 cm⁻¹ or more and 1800 cm⁻¹ or less, a ratio of the second intensity to the first intensity is equal to or greater than 1.03 and equal to or less than 1.12.

2. A silicon carbide substrate, wherein
when a first wavenumber is defined as a Raman shift at which an intensity of a Raman spectrum is maximum in a Raman shift range of 1300 cm⁻¹ or more and 1800 cm⁻¹ or less, a second wavenumber is defined as a Raman shift apart from the first wavenumber by 30 cm⁻¹ to a lower wavenumber side, a first intensity ratio is defined as a ratio of the intensity of the Raman spectrum at the first wavenumber to an intensity of the Raman spectrum at a Raman shift of 1300 cm⁻¹, a second intensity ratio is defined as a ratio of an intensity of the Raman spectrum at the second wavenumber to the intensity of the Raman spectrum at the Raman shift of 1300 cm⁻¹, a first intensity ratio difference is defined as a value obtained by subtracting the second intensity ratio from the first intensity ratio, and a second intensity ratio difference is defined as a value obtained by subtracting 1 from the first intensity ratio, the first intensity ratio is less than 1.03, or the first intensity ratio difference is less than 50% of the second intensity ratio difference.

3. The silicon carbide substrate according to claim 1, wherein
a half width of a peak of the Raman spectrum in a Raman shift range of 964 cm⁻¹±50 cm⁻¹ is equal to or less than 50 cm⁻¹.

4. The silicon carbide substrate according to claim 1, wherein
when a first peak is defined as a peak of the Raman spectrum in a Raman shift range of 964 cm⁻¹±50 cm⁻¹, a third wavenumber is defined as a Raman shift of the first peak, and a fourth wavenumber is defined as a Raman shift of the Raman spectrum having an intensity equal to one-half of an intensity of the first peak and located on a higher wavenumber side relative to the third wavenumber, a value obtained by subtracting the third wavenumber from the fourth wavenumber is equal to or less than 20 cm⁻¹.

5. The silicon carbide substrate according to claim 1, wherein
the silicon carbide substrate has a maximum diameter equal to or greater than 150 mm.

6. A silicon carbide epitaxial substrate comprising:
the silicon carbide substrate according to claim 1; and
a silicon carbide epitaxial layer provided on the silicon carbide substrate.

7. A method of manufacturing a silicon carbide semiconductor device, the method comprising:
preparing the silicon carbide epitaxial substrate according to claim 6; and
forming an electrode on the silicon carbide epitaxial layer.

8. The silicon carbide substrate according to claim 2, wherein
a half width of a peak of the Raman spectrum in a Raman shift range of 964 cm⁻¹±50 cm⁻¹ is equal to or less than 50 cm⁻¹.

9. The silicon carbide substrate according to claim 2, wherein
when a first peak is defined as a peak of the Raman spectrum in a Raman shift range of 964 cm⁻¹±50 cm⁻¹, a third wavenumber is defined as a Raman shift of the first peak, and a fourth wavenumber is defined as a Raman shift of the Raman spectrum having an intensity equal to one-half of an intensity of the first peak and located on a higher wavenumber side relative to the third wavenumber, a value obtained by subtracting the third wavenumber from the fourth wavenumber is equal to or less than 20 cm⁻¹.

10. The silicon carbide substrate according to claim 2, wherein
the silicon carbide substrate has a maximum diameter equal to or greater than 150 mm.

11. A silicon carbide epitaxial substrate comprising:
the silicon carbide substrate according to claim 2; and
a silicon carbide epitaxial layer provided on the silicon carbide substrate.

12. A method of manufacturing a silicon carbide semiconductor device, the method comprising:
preparing the silicon carbide epitaxial substrate according to claim 11; and
forming an electrode on the silicon carbide epitaxial layer.
